(19) United States
(12) Patent Application Publication
(10) Pub. No.: US 2007/0011596 A1
(43) Pub. Date: Jan. 11, 2007

(54) Parity check circuit to improve quality of memory device

(76) Inventor: Jungwon Suh, Apex, NC (US)

Correspondence Address: EDELL, SHAPIRO & FINNAN, LLC, 1901 RESEARCH BOULEVARD, SUITE 400, ROCKVILLE, MD, 20850, US

(21) Appl. No.: 11/157,869

(22) Filed: Jun. 22, 2005

(51) Int. Cl. G06F 11/00; H03M 13/00

(52) U.S. Cl. 714/800

(57) ABSTRACT

A system and method for internal error checking a semiconductor memory device in a much more area and energy efficient manner. According to the method, a predefined data pattern is written to a plurality of memory cells in the memory device. A pause or waiting time interval is initiated after the predefined data pattern is written to the plurality of memory cells. The time interval is based on temperature conditions of the memory device. After the time interval expires, the contents are read from the plurality of memory cells and a parity check operation is performed on said contents to detect any single bit error based on the predefined data pattern written to the plurality of memory cells. The circuitry required for this error checking technique is minimal, and comprises a register, a parity check circuit and a control circuit.

### FIELD OF THE INVENTION

This invention relates to semiconductor memory devices, such as dynamic random access memory (DRAM) devices, and more specifically to an on-chip error correction system and method.

### BACKGROUND OF THE INVENTION

Semiconductor memory devices commonly have error correction capability to monitor for defective memory cells. On-chip error correction techniques heretofore known require additional memory cells to store parity bits used in the error correction process. In addition, these prior art techniques burden the timing of normal memory chip operations because they require both error correction code encoding (e.g., parity bit generation) and error correction code decoding. That is, conventional error correction comprises a step to generate the parity bits and write the parity bits to the memory cells to be tested, a step to read the contents of those memory cells and perform a syndrome calculation to determine and detect any errors, and a step to correct for a memory cell having an error.

The conventional error correction techniques are not readily applicable to the new generations of memory devices used in portable, battery-powered, devices. Power consumption in a portable device is a critical measure of performance and whenever possible, consumption should be reduced to extend battery life. New error correction techniques are needed for memory devices designed for portable/battery-powered applications that maintain quality and performance of the memory device without increasing the cost, size and power consumption of the memory device.

### SUMMARY OF THE INVENTION

Briefly, a system and method are provided for internal error checking a semiconductor memory device in a much more area and energy efficient manner. According to the method, a predefined data pattern is written to a plurality of memory cells in the memory device. A pause or waiting time interval is initiated after the predefined data pattern is written to the plurality of memory cells. The time interval is based on temperature conditions of the memory device. After the time interval expires, the contents are read from the plurality of memory cells and a parity check operation is performed on said contents to detect any single bit error based on the predefined data pattern written to the plurality of memory cells.

The circuitry required for this error checking technique is minimal, and comprises a register, a parity check circuit and a control circuit. The register stores a predefined data pattern. The parity check circuit performs a parity check operation on data read from the memory cells. The control circuit generates one or more control signals from which row address and column address signals control writing the predefined data pattern to the plurality of memory cells, and subsequently reading out of the contents of the plurality of memory cells to the parity check circuit. The parity check circuit operates on the contents read out from the cells in order to detect any single bit error based on the predefined data pattern written to the plurality of memory cells.

Objects and advantages of the techniques described herein will become more readily apparent when reference is made to the following description taken in conjunction with the accompanying drawings.

### BRIEF DESCRIPTION OF THE DRAWINGS

FIG. 1 is a block diagram of the on-chip error checking system for a memory device.

FIG. 2 is a block diagram of a mode register showing how the on-chip error checking system may be enabled and disabled by a bit in a mode register.

FIGS. 3A and 3B are timing diagrams showing when the on-chip error checking scheme may be activated with respect to operation modes of the memory device.

FIG. 4 is a more detailed timing diagram depicting operation of the on-chip error checking scheme.

### DETAILED DESCRIPTION

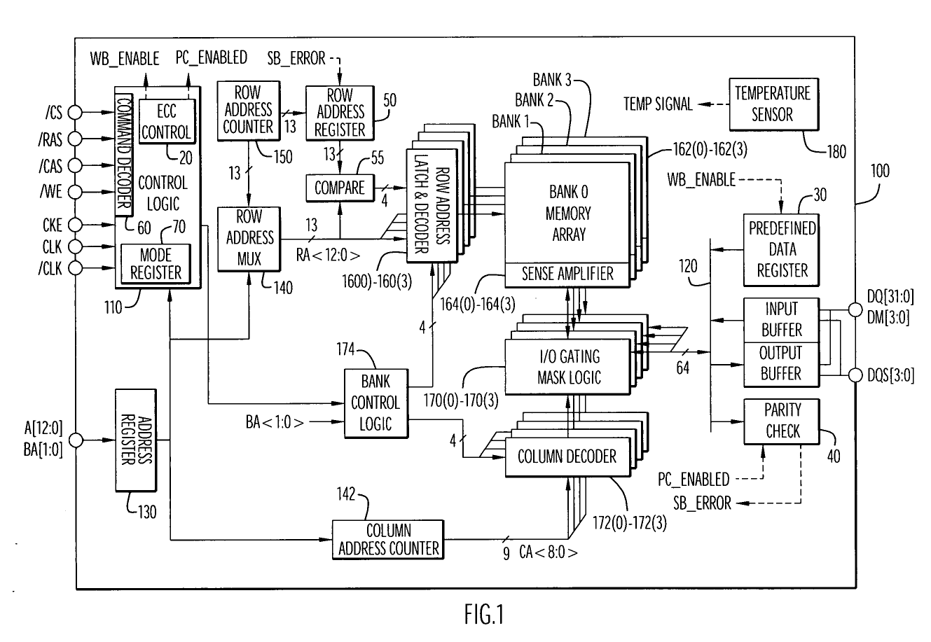

Referring first to FIG. 1, a block diagram of the on-chip error checking system is shown in the context of a 512 Mbyte Double Data Rate (DDR) synchronous dynamic random access memory (SDRAM). It should be understood that the system and methods described herein may be useful in any type of semiconductor memory device. FIG. 1 illustrates a memory device 100 and its components that are relevant to the error checking system described herein. Other components not shown in FIG. 1 may be present depending on the type of memory device.

The components of the error checking system consist of an error code checking (ECC) control circuit 20, a register 30 that stores a predefined data pattern, and a parity check circuit 40, a row address register 50 and a compare circuit 55. Parameters for controlling the error checking system 10 are stored in a mode register 70. These components interact with other components that are common to most semiconductor memory devices. For example, the ECC control circuit 20 may be included as part of a control logic block 110 that also includes the mode register 70 and a command decoder 60. The register 30 and parity check circuit 40 are coupled to a bus 120 that in turn connects to various other components in the memory device.

The memory device 100 further includes an address register 130 that is connected to the control logic block 110, a row address multiplexer (MUX) 140 and a column address counter 142. A row address counter 150 is connected to the row address multiplexer 140 and to the row address register 50. There is a plurality of row address latch and decoder blocks 160(0) to 160(3), each of which is associated with a corresponding memory array bank 162(0) to 162(3). In addition, associated with each bank 162(0) to 162(3) is a corresponding sense amplifier block 164(0) to 164(3). Furthermore, there are input/output (I/O) gating mask logic blocks 170(0) to 170(3) for a corresponding memory array bank, and a column decoder 172(0) to 172(3) for a corresponding I/O gating mask logic block. The column decoders 172(0) to 172(3) are controlled by outputs from the column address counter 142 and a bank control logic circuit 174.

The bus 120 connects, among other components, the register 30 and parity check circuit 40 to the I/O gating mask logic blocks 170(0) to 170(3). As a result, the predetermined data pattern stored in the register 30 can be written to one of the memory array banks 162(0) to 162(3), and subsequently the contents read from one of the memory array banks 162(0) to 162(3) can be coupled to the parity check circuit 40 for parity check operations.

In addition, an on-chip temperature sensor 180 may be provided. The temperature sensor 180 is useful to produce a signal (Temp Signal) that represents current temperature conditions of the memory device 100. A time period or “pause interval” may be generated on the basis of the Temp Signal.

The signals produced by the error correction circuitry are as follows.

ECC Control Circuit 20: Write Bank Enable, WB_Enable
Parity Check Enable, PC_Enable

Parity Check Circuit 40: Single Bit Error Indication Signal, SB_Error

The WB_Enable signal is coupled to the register 30. The SB_Error signal is coupled to the row address register 50. Again, the SB_Error signal indicates a row address for a row, or a column address for a column, of memory cells that contains a single bit error.

Data values according to the predefined data pattern stored in the register 30 are written to memory cells according to so called data scrambling such that its parity is already known. Because a cell is connected to BL or /BL and a bit line sensing amplifier is shared between cell blocks, the physical data (i.e., the real data written to a cell) is not always the same as the logical data (i.e., the external data). For example, if “H” data is to be written to the specific cell, the physical data that is written may be “H” or “L” according to the location of the cell. This so called “data scrambling” depends on how each cell is located according to data polarity. For example, if perfect checker board data patterns (e.g., “HLHL” to 4 cells) to all memory cells are desired, then it may be necessary to invert or not to invert the data patterns according to the data scrambling. This data scrambling principal is well known in the art of semiconductor memory device design.

The parity check circuit 40 generates the one bit parity result through Exclusive-OR logic. As a result any single bit error may be detected when examining the contents of the storage cells read out after the predefined data pattern is written. Moreover, any word size can be used as a parity check unit because the data pattern is repeated.

In addition, when a bit error is detected and its location identified, row and/or column redundancy may be used to account for the error. If column redundancy is used, an additional column address register is needed, though this column address register is not shown in FIG. 1 for simplicity. The stored row (or column) address for the bit error is used as redundancy information to improve memory quality. Furthermore, extended self refresh may be invoked to further reduce the self refresh current IDD6.

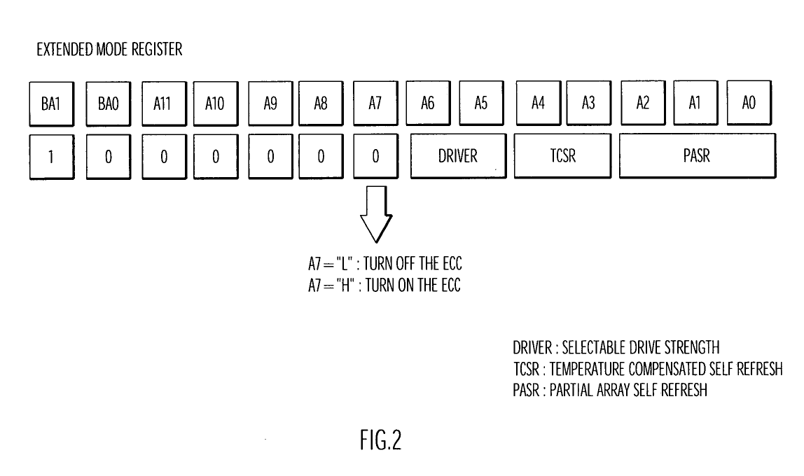

Turning to FIG. 2, the structure of the mode register 70 is shown. The mode register 70 includes fields for a variety of memory device control parameters, including the on-chip error code correction function. For example, one bit of the mode register 70, such as the A7 bit, can be used to enable or disable the on-chip error correction functions. When error correction is enabled, a more aggressive internal self refresh period may be applied to reduce the self refresh current, IDD6. This is particularly desirable for a mobile memory device, where power conservation is an important performance factor. Parameters for Drive Strength (Driver), Temperature Compensated Self Refresh (TCSR) and Partial Array Self Refresh (PASR) are used to set the more aggressive low power features desirable in low power DRAM devices, for example.

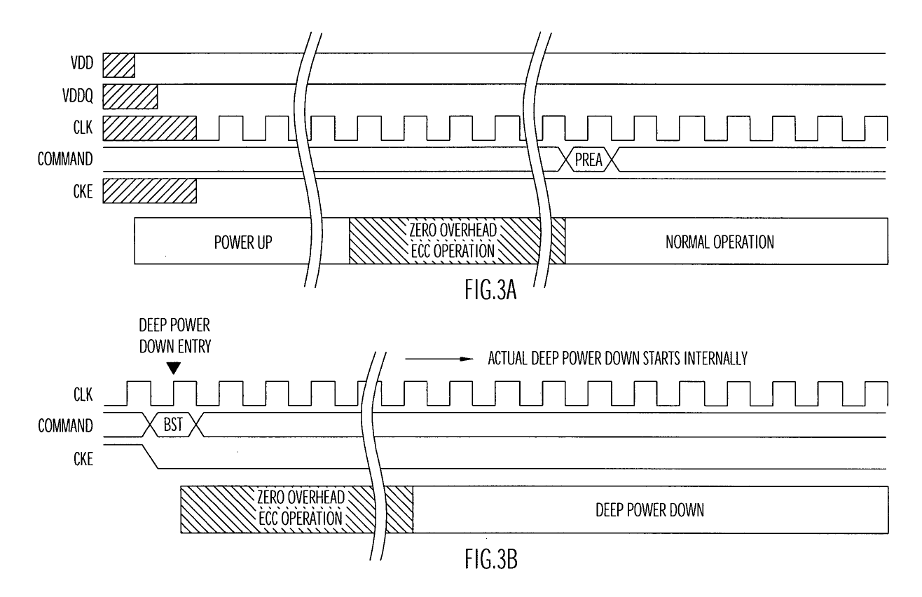

Reference is now made to FIGS. 3A and 3B for a generalized understanding of the timing associated with the error correction technique. The error correction operation is invoked when a memory array bank is empty. For example, the operation is invoked after “power up” or just before “deep power down” so as not to impose any timing overhead on normal memory device operations. FIG. 3A shows the signal timing when the error correction operation is invoked after power up. There is a short time interval after power up and before normal operation during which the error correction operations are activated. FIG. 3B shows that the error correction operations may also be initiated after the deep power down entry mode begins, but just before the device enters deep power down. As is known in the art, deep power down is different from normal power down. All data is lost during the deep power down mode, whereas all data is maintained during normal power down.

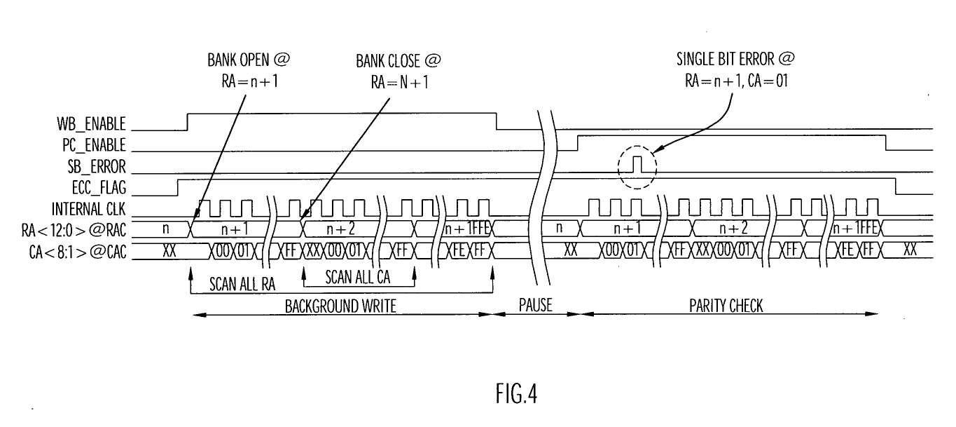

The error correction operation can be interrupted at any time. For example, the precharge all (PREA) or “deep power down exit” command may interrupt the error correction operation. If interruption occurs, the internal error correction operation is terminated immediately so that there are no external timing restrictions due to the error correction operation. The row or column replacement and self refresh period extension are executed only after all internal error correction operations are completed. Row or column replacement is a “soft” repair and useful until and unless power to the memory device has been shut down. An internal flag signal ECC_flag (FIG. 4) is used to determine when the error correction operation is completed.

Turning to FIG. 4 in conjunction with FIG. 1, a detailed description of the error correction operation is provided. The error correction operation essentially consist of three phases: (1) background write of the predetermined data pattern to all memory cells in a memory array bank; (2) pause for a time interval based on temperature sensor information; (3) read contents from the memory array bank and perform parity checking to detect any single bit errors. The flag signal ECC_Flag goes high upon initiation of the error correction operation, and stays high until the operation is completed. The WB_Enable signal initiates the background writing process of the predefined data pattern to one of the memory array blocks. During the time interval that the WB_Enable signal is high, the control logic circuit 110 controls the row address counter 150 and column address counter 142 as shown in FIG. 4 to write the predefined data pattern to each memory cell (column addresses “00” to “FF”) of each row, from row n to row n+1FFE, in a memory bank. After the predefined data pattern has been written to each of the rows of the memory array bank, the pause interval occurs. Again, the pause interval is to allow for a certain time period to transpire according to the current temperature conditions of the memory device, before initiating the read and parity check operation. The background write operation can be accelerated if multiple wordlines are simultaneously activated. For example, the write operation can be executed at a given row address for all banks simultaneously to reduce overall write time. That is, wordlines are activated in each memory cell bank and the background write operation is performed to all banks simultaneously, in a row-by-row fashion.

After the pause interval, the ECC control circuit generates the PC_Enable signal to initiate reading out and parity checking, and stays high until the parity check phase is completed. The control logic circuit 110 generates the row address and column address signals to read out the contents of the memory cells in the memory array bank to which the predefined data pattern was written. The contents of the memory cells are read out in a manner similar to how it was written. All the memory cells are read from one row, then the memory cells from another row, and so on. When and if the parity check circuit detects a single bit error during the parity check phase, it generates a pulse in the SB_Error signal synchronized to the row address and column address of the memory cell having the error, as shown in the example in FIG. 4. After the read and parity check phase is completed, the PC_Enable signal goes low and the ECC_flag signal subsequently goes low, signifying completion of the error correction process. Only the read operation is executed in the parity check operation. Consequently, internal data bus lines can accommodate all read data from all banks (e.g., 4 banks in a 512 Mbyte chip) using local Exclusive-OR circuits. To be more specific, there is a 64 bit internal data bus in a 512 Mbyte SDRAM device, and each memory bank produces 64 bit data. In this case, each bank has 4-input Exclusive-OR circuits and produces only compressed 16 bit data after an Exclusive-OR calculation. Thus, the parity check circuit 40 may comprise an Exclusive-OR tree for the 64 bit data to perform the parity check operation. Numerous other parity check circuit and techniques heretofore known or hereinafter developed may also be employed on the contents read out from the memory cells.

The SB_Error signal is coupled to the row address register 50. The row address register 50 responds to the SB_Error signal to store the row address that contains the single bit error. Alternatively, as indicated above, a similar register may also be provided to store the column address that contains the single bit error. Thus, the comparator circuit 55 can compare the row address supplied to it by the row address register 50 with the row address supplied by the row address multiplexer 140 so that when the row which contains a single bit error is to be accessed, a redundant row is accessed instead. An alternative to using redundancy to replace a row or column with a bit error is to use a register to replace the row containing the single bit error. After completing the internal error correction operation, an extended self refresh period may be applied to reduce the self refresh current (IDD6).

The advantages of the on-chip error correction operation described herein include minimal circuitry for implementation, applicability to memory devices for mobile applications and minimal impact on self refresh current. The error correction operation involves only simple parity checking, and does not require parity bit generation or error correction circuitry. Thus, the circuitry required to implement this technique is minimal, and does not change an existing memory chip design and layout. This contributes to reducing the size of the memory chip, thus making it more suitable for multiple chip packaging. The error correction operation can be interrupted at any time, thereby imposing no external timing restriction. After completing the internal error correction operation, an extended self refresh period is executed to reduce the self refresh current. Thus, for any or all of the reasons described above, this error correction system and method is useful in memory devices, such as DRAMs, for mobile applications.

In sum, a method is provided for internal error checking memory cells of a semiconductor memory device, comprising: (a) writing a predefined data pattern to a plurality of memory cells in the memory device; and (b) reading contents from the plurality of memory cells and performing a parity check on said contents to detect any single bit error based on the predefined data pattern written to the plurality of memory cells. After writing the predefined data pattern to the memory cells, a time interval is allowed to transpire before reading the contents of the memory cells and performing the parity check analysis on said contents. The time interval may be based on temperature conditions of the memory device.

In addition, a method is provided for internal error checking a semiconductor memory device, comprising: writing a predefined data pattern to a plurality of memory cells in the memory device; reading contents from the plurality of memory cells and performing a parity check on said contents to detect any single bit error based on the predefined data pattern written to the plurality of memory cells; and storing an indication of the row address of the row or the column address of the column of memory cells having the single bit error.

Similarly, a semiconductor memory device is provided comprising: a plurality of memory cells; a register containing a predefined data pattern; a parity check circuit that performs a parity check operation on data supplied thereto; and a control circuit that generates one or more control signals from which address signals are produced that control writing of the predefined data pattern to the plurality of memory cells, and reading of the contents of the plurality of memory cells to the parity check circuit for performing the parity check operation on said contents in order to detect any single bit error based on the predefined data pattern written to the plurality of memory cells.

In addition, a semiconductor memory device comprising: a plurality of memory banks, each memory bank having a plurality of memory cells arrange in a row and column array; a register containing a data pattern; a parity check circuit that performs a parity check operation on data supplied thereto; and a control circuit that generates one or more control signals from which are produced address signals that control writing of the data pattern to a memory bank, and reading of the contents from one of the memory banks to the parity check circuit that performs the parity check operation on said contents in order to detect any single bit error based on the data pattern written to the memory cells in a memory bank.

The device and methods described herein may be embodied in other specific forms without departing from the spirit or essential characteristics thereof. The foregoing embodiments are therefore to be considered in all respects illustrative and not meant to be limiting.

What is claimed is:

1. A method for internal error checking a semiconductor memory device, comprising:
a. writing a predefined data pattern to a plurality of memory cells in the memory device; and
b. reading contents from the plurality of memory cells and performing a parity check on said contents to detect any single bit error based on the predefined data pattern written to the plurality of memory cells.

2. The method of claim 1, wherein (a) writing comprises background writing the predefined data pattern to the plurality of memory cells.

3. The method of claim 1, and further comprising waiting a time interval after (a) writing.

4. The method of claim 3, and further comprising sensing temperature conditions of the memory device, and wherein said waiting comprises waiting for a period of time based on the temperature conditions of the memory device.

5. The method of claim 1, wherein (b) reading and performing the parity check comprises performing the parity check as contents are read out from the plurality of memory cells.

6. The method of claim 1, and further comprising detecting a single bit error based on the parity check.

7. The method of claim 6, and further comprising storing an indication of the row address or column address associated with a single bit error.

8. The method of claim 7, and further comprising writing to a redundant row or redundant column of memory cells when access is to be made to a row or column containing a single bit error.

9. The method of claim 7, and further comprising writing to a register when access is to be made to a row or column containing a single bit error.

10. The method of claim 1, wherein writing comprises simultaneously writing the predefined data pattern using multiple wordlines associated with a bank of memory cells.

11. The method of claim 1, wherein (a) writing and (b) reading are invoked during a time interval after power up and prior to normal operation of the memory device.

12. The method of claim 1, wherein (a) writing and (b) reading are invoked prior to deep power down of the memory device.

13. A semiconductor memory device comprising:
a. a plurality of memory cells;
b. a register containing a predefined data pattern;
c. a parity check circuit that performs a parity check operation on data supplied thereto; and
d. a control circuit that generates one or more control signals from which address signals are produced that control writing of the predefined data pattern to the plurality of memory cells, and reading of the contents of the plurality of memory cells to the parity check circuit that performs the parity check operation on said contents in order to detect any single bit error based on the predefined data pattern written to the plurality of memory cells.

14. The memory device of claim 13, and further comprising a bus coupled to the parity check circuit and to the register, wherein the bus transports the predefined data pattern to a plurality of memory cells and transports contents read from the plurality of memory cells to the parity check circuit.

15. The memory device of claim 13, wherein the control circuit is responsive to an error check control signal to write the predefined data pattern to the plurality of memory cells as a background write operation.

16. The memory device of claim 13, wherein the control circuit waits a time period after writing of said predetermined data pattern before initiating reading of said contents.

17. The memory device of claim 16, wherein the control circuit is responsive to a signal representing temperature conditions of the memory device, and wherein said time period is based on said signal.

18. The memory device of claim 13, wherein the parity check circuit performs the parity check operation as said contents is read out from the plurality of memory cells.

19. The memory device of claim 18, wherein the parity check circuit generates a bit error indication signal that indicates a row address for a row or a column address for a column of memory cells that contains a single bit error.

20. The memory device of claim 19, and further comprising a row address register that is responsive to the bit error indication signal to store the row address for the row of memory cells that contains a single bit error.

21. The memory device of claim 20, and further comprising a comparator coupled to the row address register, wherein the comparator compares a content of the row address register with a row address for a row of the plurality of memory cells to output an indication when the row address coincides with the content of the row address register.

22. A method for internal error checking a semiconductor memory device, comprising:
a. writing a predefined data pattern to a plurality of memory cells in the memory device;
b. waiting a time interval after the predefined data pattern is written to the plurality of memory cells, wherein said time interval is based on temperature conditions of the memory device; and
c. reading contents from the plurality of memory cells and performing a parity check on said contents to detect any single bit error based on the predefined data pattern written to the plurality of memory cells.

23. The method of claim 22, wherein (a) writing comprises writing data values from the predefined data pattern sequentially to the memory cells of a row of cells in a memory cell array bank, repeating said writing of data values for each of the plurality of rows of memory cells in the memory cell array bank.

24. The method of claim 23, wherein (c) reading comprises sequentially reading contents from the memory cells of a row of the memory cell bank and performing parity check on said contents as it is read out from the row of memory cells, and repeating sequentially reading of the contents from the memory cells for each of the plurality of rows of memory cells in the memory cell array bank.

25. The method of claim 23, and further comprising storing an indication of the row address or column address associated with a single bit error.

26. The method of claim 25, and further comprising writing to a redundant row or redundant column when access is to be made to a row or column containing a single bit error.

27. A method for internal error checking a semiconductor memory device, comprising:
a. writing a predefined data pattern to a plurality of memory cells in the memory device;
b. reading contents from the plurality of memory cells and performing a parity check on said contents to detect any single bit error based on the predefined data pattern written to the plurality of memory cells; and
c. storing an indication of the row address of the row or the column address of the column of memory cells having the single bit error.

28. The method of claim 27, wherein (a) writing comprises writing data values from the predefined data pattern sequentially to the memory cells of a row of memory cells in a memory cell array bank, repeating said writing of data values for each of the plurality of rows of memory cells in the memory cell array bank.

29. The method or claim 28, wherein (b) reading comprises reading contents sequentially from the memory cells of a row of the memory cell bank and performing parity check on said contents as it is sequentially read out from the row of memory cells, and repeating reading of the contents sequentially from the memory cells for each of the plurality of rows of memory cell sin the memory cell array bank.

30. The method of claim 27, wherein (a) writing and (b) reading are invoked during a time interval after power up and prior to normal operation of the memory device.

31. The method of claim 27, wherein (a) writing and (b) reading are invoked prior to deep power down of the memory device.

32. A method for internal error checking a semiconductor memory device when the memory device is not in normal operation, comprising performing an error checking of the memory device by (a) writing a predefined data pattern to a plurality of memory cells in the memory device; and (b) reading contents from the plurality of memory cells and performing a parity check on said contents to detect any single bit error based on the predefined data pattern written to the plurality of memory cells.

33. The method of claim 32, wherein (a) writing and (b) reading are invoked during a time interval after power up and prior to normal operation of the memory device.

34. The method of claim 32, wherein (a) writing and (b) reading are invoked prior to power down of the memory device.

35. A semiconductor memory device comprising:
a. a plurality of memory cells;
b. means for storing a data pattern;
c. parity checking means for performing a parity check operation on data supplied thereto; and
d. control means for initiating writing of the data pattern from the means for storing to the plurality of memory cells, and subsequent reading of the contents of the plurality of memory cells to the parity checking means that performs the parity check operation on said contents in order to detect any single bit error based on the data pattern written to the plurality of memory cells.

36. The memory device of claim 35, wherein the control means waits a time period after writing said data pattern to said plurality of memory cells before initiating reading of said contents from said memory cells.

37. The memory device of claim 25, wherein the parity checking means generates a bit error indication signal that indicates a row address for a row, or a column address for a column, of memory cells that contains a single bit error.

38. The memory device of claim 37, and further comprising means for storing that is responsive to the bit error indication signal to store the row address for the row or the column address for the column of memory cells that contains a single bit error.

39. A semiconductor memory device comprising:
a. a plurality of memory banks, each memory bank having a plurality of memory cells arrange in a row and column array;
b. a register containing a data pattern;
c. a parity check circuit that performs a parity check operation on data supplied thereto; and
d. a control circuit that generates one or more control signals from which are produced address signals that control writing of the data pattern to one of the memory banks, and reading of the contents from one of the memory banks to the parity check circuit that performs the parity check operation on said contents in order to detect any single bit error based on the data pattern written to the memory cells in a memory bank.

40. The memory device of claim 39, wherein the control circuit generates control signals to initiate writing of data values from the data pattern sequentially to the memory cells of a row in a memory bank, and repeating writing of data values for each of the plurality of rows of memory cells in the memory bank.

41. The memory device of claim 39, wherein the control circuit generates control signals to initiate sequentially reading of contents from memory cells of a row of a memory bank, and repeating sequentially reading of the contents from the memory cells for each of the plurality of rows in a memory bank.
